(19) United States
(12) Patent Application Publication
(10) Pub. No.: US 2010/0327169 A1
(43) Pub. Date: Dec. 30, 2010

(54) X-RAY DETECTOR

(76) Inventor: Alexander Korn, Effeltrich (DE)

Correspondence Address: King & Spalding LLP, 401 Congress Avenue, Suite 3200, Austin, TX, 78701, US

(21) Appl. No.: 12/795,465

(22) Filed: Jun. 7, 2010

(30) Foreign Application Priority Data
Jun. 8, 2009 (DE) 10 2009 024 225.2

(51) Int. Cl. G01T 1/20; H01L 31/18

(52) U.S. Cl. 250/363.01; 438/24; 257/E31.095

(57) ABSTRACT

In order to ensure an even image quality of digital X-ray recordings, provision is made for an X-ray detector with light-sensitive pixel elements arranged in an active readout matrix and with a reset-light source arranged therebehind in the radiation direction of X-ray radiation, wherein the reset-light source is designed as a planar OLED (organic light-emitting diode) matrix applied to a film.

### CROSS-REFERENCE TO RELATED APPLICATIONS

This application claims priority to DE Patent Application No. 10 2009 024 225.2 filed Jun. 8, 2009, the contents of which is incorporated herein by reference in its entirety.

### TECHNICAL FIELD

The invention relates to an X-ray detector with light-sensitive pixel elements arranged in an active matrix.

### BACKGROUND

Digital X-ray detectors, based on active readout matrices, e.g. made of amorphous silicon (a-Si), with a scintillator layer layered in front, have been known for a few years. The incident X-ray radiation is converted into visible light in the scintillator layer, is converted into electric charge in the light-sensitive pixel elements of the readout matrix, and is stored in a spatially-resolved fashion. Related techniques likewise use an active pixel matrix made of amorphous silicon, but in combination with an X-ray converter (e.g. selenium) that directly converts the incident X-ray radiation into electric charge. Said charge is then stored on an electrode of the readout matrix in a spatially-resolved fashion. The stored charge is subsequently read out electronically by an active circuit element, converted into digital signals, and transmitted to an electronic image processing system.

In order to reduce ghost-image artifacts, that is to say charges of the preceding recording not being read out completely from the amorphous silicon, it is known to apply a board of light-emitting diodes as reset light below the active readout matrix and thereby stabilize and homogenize the amorphous silicon by means of defined emitted light pulses.

However, light-emitting diodes often have locally-varying brightness distributions or vary slightly from one another in respect of their power, and so there sometimes is an uneven reset distribution, which is then mirrored in the digital X-ray recording. This effect is corrected by an offset correction with an empty image without X-ray radiation. However, the so-called “grid effect” artifact can result in the X-ray detector from mechanical warping of the reset light if e.g. there is a change in the orientation of the X-ray detector in space. The brightness profile of the reset light is displaced in the effect. If a recorded X-ray image is corrected by an empty image recorded at a different, slightly displaced position as a result of the mechanical warping, a residual then remains, which becomes visible in the X-ray image as an artifact. The effect occurs particularly when applying continuous X-ray radiation because in this case the reset light has to be applied at the same time as the X-ray radiation.

### SUMMARY

According to various embodiments, an even image quality of digital X-ray recordings can be ensured in the case of an X-ray detector with reset light.

According to an embodiment, an X-ray detector may comprise light-sensitive pixel elements arranged in an active readout matrix and a reset-light source arranged therebehind in the radiation direction of X-ray radiation, wherein the reset-light source is designed as a planar OLED (organic light-emitting diode) matrix applied to a film.

According to a further embodiment, the OLED matrix film can be applied to the rear side of a substrate supporting the active readout matrix. According to a further embodiment, the OLED matrix film can be adhesively bonded to the rear side of the substrate. According to a further embodiment, the OLED matrix film may have at least the same area as the active readout matrix. According to a further embodiment, the OLED matrix film may have a flexible design. According to a further embodiment, the OLED matrix may have polymers, in particular polyphenylene vinylene or polyfluorene.

### BRIEF DESCRIPTION OF THE DRAWINGS

The invention and further refinements according to the features of the dependent claims are explained in more detail in the following text on the basis of schematically illustrated exemplary embodiments in the drawing, without this restricting the invention to these exemplary embodiments. In the drawings:

FIG. 1 shows a lateral section through an X-ray detector with a reset-light source according to the prior art, and

FIG. 2 shows a lateral section through an X-ray detector according to various embodiments with an OLED film as a reset-light source.

### DETAILED DESCRIPTION

In the case of the X-ray detector according to various embodiments with light-sensitive pixel elements arranged in an active readout matrix and with a reset-light source arranged therebehind in the radiation direction of X-ray radiation, the reset-light source is designed as a planar OLED (organic light-emitting diode) matrix applied to a film. OLEDs are organic light-emitting diodes, which can be applied in a large scale on thin substrates such as films and which generate a particularly homogeneous, even light distribution. As a result of this, the reset-light source can illuminate the active readout matrix in an even and stable fashion and, due to the even light distribution, there are no brightness variations as a result of mechanical displacements in the X-ray detector. As a result of this, the quality of the generated X-ray images is improved in turn, since neither ghost-image artifacts nor the grid effect are able to influence the X-ray images.

According to an embodiment, the OLED matrix film is arranged on the rear side of a substrate, generally a glass substrate, supporting the active readout matrix. As a result of this, the reset-light source is arranged directly behind the active matrix and there is no loss in radiation power as a result of scattered radiation or intermediate layers.

Advantageously, the OLED matrix film is adhesively bonded to the rear side of the substrate for a particularly stable and simple attachment of the reset-light source on the substrate.

According to a further embodiment, the OLED matrix film has at least the same area as the active readout matrix. This illuminates the entire readout matrix in an even fashion and there cannot be artifacts at the edges either.

Advantageously, the OLED matrix film has a flexible design. As a result of this, the film matches the substrate in a particularly simple fashion and it can also compensate for small mechanical deformations without restrictions.

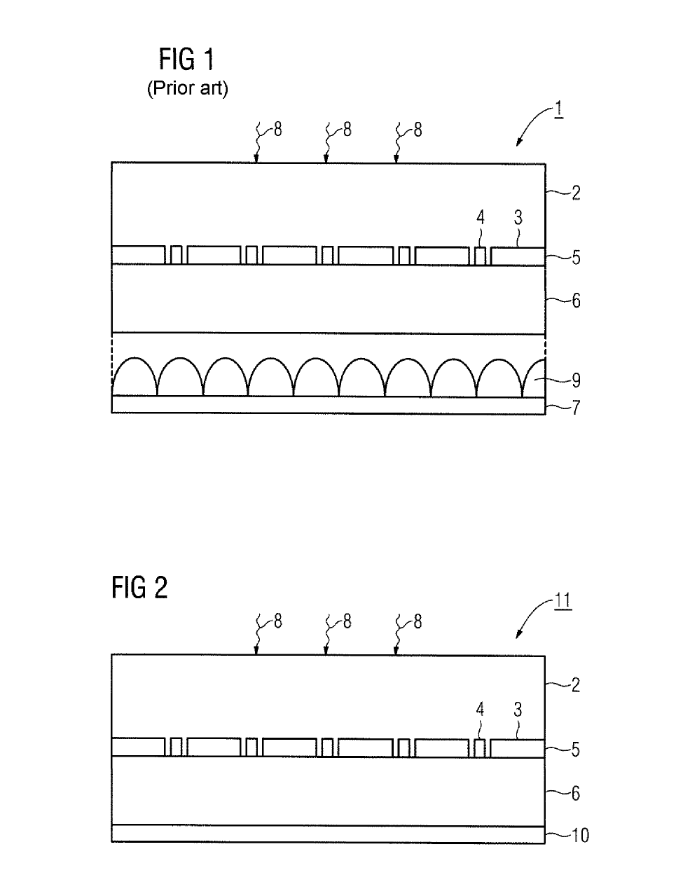

FIG. 1 shows a digital X-ray detector 1 as per the prior art. It has a scintillator layer 2, for example consisting of a multiplicity of parallel grown CsI needles. This scintillator layer 2 is coupled (generally adhesively-bonded) to an active readout matrix 5, for example made of amorphous or crystalline silicon. The readout matrix 5 consists of a multiplicity of individual pixel elements 3, 4, which each comprise a photodiode 3 with an associated switching element 4. The readout matrix 5 is arranged on a substrate 6, which is particularly transparent to visible light and is a glass substrate in this case. There usually is furthermore a thin adhesive layer (not illustrated), e.g. a gel, between the scintillator and the silicon. The X-ray detector 1 moreover has a conventional reset-light source made of a multiplicity of inorganic light-emitting diodes 9, which are arranged on a printed circuit board 7 behind the substrate 6 in respect of the radiation direction of X-ray radiation 8. By way of example, the light-emitting diodes can be switched together. Moreover, the prior art has also disclosed reset-light sources, which are switched in regions with respectively eight light-emitting diodes. The semiconductor layer of such an inorganic light-emitting diode is formed by indium gallium nitride, for example.

FIG. 2 shows an X-ray detector 11 according to various embodiments, which has a reset-light source in the form of an OLED (organic light-emitting diode) matrix 10 applied to a film. Such an OLED matrix film 10 can be adhesively bonded to e.g. the rear side of the glass substrate on which the active readout matrix is situated. The film can be made of a flexible plastic, for example from PET (polyethylene terephthalate). The OLED matrix is applied to the film and has semiconductor layers, e.g. made of polymers, such as a polyphenylene vinylene or polyfluorene.

In general OLEDs are designed as a metal-polymer/polymer-semiconductor interface. There is an organic emitter-layer (recombination layer) on an anode (made of e.g. indium tin oxide). An organic electron-conduction layer is then applied thereon. It is terminated by a cathode, consisting of a metal or an alloy (for example calcium, aluminum, barium, ruthenium, magnesium-silver alloy).

An OLED functions as follows: A voltage is applied, with the anode having a positive charge with respect to a cathode. As a result of this, electrons are now injected by the cathode, while the anode provides the holes. As a result of this, the emitter-layer is charged negatively and the conduction layer is positive as a result of the holes. Hole and electron drift toward one another and ideally meet in the emitter-layer, which is why this layer is also referred to as a recombination layer. Photons are emitted as a result of the recombination. Plastics such as polyphenylene vinylene or polyfluorene, which illuminate brightly when an electric voltage is applied, are suitable materials for OLEDs.

The OLED matrix, that is to say a multiplicity of OLEDs next to one another, can be applied in a very thin fashion and over a large area, and is very cost-effective in production. In the case of particularly large active readout matrices, it is also possible for a plurality of OLED matrix films to be adhesively bonded next to one another on the glass substrate. An OLED matrix has a particularly homogenous and even large-scale light distribution because the individual OLEDs can be arranged as a particularly thin layer. This light from an OLED matrix likewise has particularly high luminosity and a high contrast.

Thus, according to various embodiments, in summary: In order to ensure an even image quality of digital X-ray recordings, provision is made for an X-ray detector with light-sensitive pixel elements arranged in an active readout matrix and with a reset-light source arranged therebehind in the radiation direction of X-ray radiation, wherein the reset-light source is designed as a planar OLED (organic light-emitting diode) matrix applied to a film.

What is claimed is:

1. An X-ray detector comprising light-sensitive pixel elements arranged in an active readout matrix and a reset-light source arranged therebehind in the radiation direction of X-ray radiation, wherein the reset-light source is designed as a planar OLED (organic light-emitting diode) matrix applied to a film.

2. The X-ray detector according to claim 1, wherein the OLED matrix film is applied to the rear side of a substrate supporting the active readout matrix.

3. The X-ray detector according to claim 1, wherein the OLED matrix film is adhesively bonded to the rear side of the substrate.

4. The X-ray detector according to claim 1, wherein the OLED matrix film has at least the same area as the active readout matrix.

5. The X-ray detector according to claim 1, wherein the OLED matrix film has a flexible design.

6. The X-ray detector according to claim 1, wherein the OLED matrix has polymers.

7. The X-ray detector according to claim 6, wherein the polymers are polyphenylene vinylene or polyfluorene.

8. An X-ray detector comprising:
a scintillator layer which is coupled to an active readout matrix, and
a reset-light source arranged there behind in the radiation direction of X-ray radiation, wherein the reset-light source is designed as a planar OLED (organic light-emitting diode) matrix applied to a film.

9. The X-ray detector according to claim 8, wherein the scintillator comprises a multiplicity of parallel grown CsI needles.

10. The X-ray detector according to claim 8, wherein the scintillator is adhesively-bonded to the active readout matrix which is made of amorphous or crystalline silicon.

11. The X-ray detector according to claim 8, wherein the active readout matrix comprises a multiplicity of individual pixel elements which each comprise a photodiode with an associated switching element.

12. The X-ray detector according to claim 8, wherein the readout matrix is arranged on a substrate which is transparent to visible light.

13. The X-ray detector according to claim 12, comprising a thin adhesive layer or a gel between the scintillator and the active readout matrix.

14. The X-ray detector according to claim 8, wherein the OLED matrix film is applied to the rear side of a substrate supporting the active readout matrix.

15. The X-ray detector according to claim 8, wherein the OLED matrix film is adhesively bonded to the rear side of the substrate.

16. The X-ray detector according to claim 8, wherein the OLED matrix film has at least the same area as the active readout matrix.

17. The X-ray detector according to claim 8, wherein the OLED matrix film has a flexible design.

18. The X-ray detector according to claim 8, wherein the OLED matrix has polymers selected from the group consisting of polyphenylene vinylene and polyfluorene.

19. A method for providing an X-ray detector, comprising:
arranging light-sensitive pixel elements in an active readout matrix and
arranging a reset-light source there behind in the radiation direction of X-ray radiation, wherein the reset-light source is designed as a planar OLED (organic light-emitting diode) matrix applied to a film.

20. The method as claimed in claim 19, wherein the OLED matrix film is adhesively bonded to the rear side of the substrate.
